(19) United States
(12) Patent Application Publication
(10) Pub. No.: US 2016/0181087 A1
(43) Pub. Date: Jun. 23, 2016

(54) Particle removal with minimal etching of silicon-germanium

(71) Applicants: Intermolecular Inc., San Jose, CA (US); IBM-International Business Machines Corporation, Armonk, NY (US)

(72) Inventors: John Foster, Mountain View, CA (US); Steven Bentley, Watervliet, NY (US); Sean Lin, Watervliet, NY (US); Dave Rath, Stormville, NY (US); Muthumanickam Sankarapandian, Yorktown Heights, NY (US); Ruilong Xie, Niskayuna, NY (US)

(21) Appl. No.: 14/576,554

(22) Filed: Dec. 19, 2014

(51) Int. Cl. H01L 21/02; B08B 3/10; B08B 3/08

(52) U.S. Cl. CPC H01L 21/02082; H01L 21/02068; B08B 3/08; B08B 3/10

(57) ABSTRACT

Particle-clean formulations and methods for semiconductor substrates use aqueous solutions of tetraethylammonium hydroxide (“TEAH,” C₈H₂₁NO) with or without hydrogen peroxide (H₂O₂). The solution pH ranges from 8-12.5. At process temperatures between 20-70 C, the TEAH solutions have been observed to remove particles from silicon-germanium (SiGe) with 20-99% Ge content in 15-300 seconds with very little etching (SiGe etch rates<1 nm/min).

### BACKGROUND

Related fields include cleaning of wafers and other semiconductor substrates; in particular, removing particles from silicon-germanium (SiGe) surfaces with significant (˜20-99%) Ge content (hereinafter “20-99% SiGe”).

Advances in epitaxial growth of pseudomorphic SiGe have increased interest in these materials for applications requiring high carrier mobility, such as high-speed complementary circuits. Unfortunately, many standard chemistries and processes developed for Si are not compatible with Ge. In SiGe, these incompatibilities begin to emerge as the Ge content increases.

As feature sizes decrease in semiconductor devices, tolerance for particles (and any pits, scratches, or residues they may leave behind) also decreases. Particles can have many origins; ambient atmosphere, incompletely-rinsed slurries, crumbled brittle-material sputtering targets, buildup on process-chamber walls, photoablation ejecta, residues from etching or annealing, and compromised container seals are but a few examples. Particles can adhere at any point in device fabrication, before or after patterning.

Formulations and methods for removing particles from surfaces (collectively, “particle cleans”) are, in general, intended to leave the underlying surface intact rather than etching it or otherwise altering it. “Etching” is used herein to mean “removal of at least part of a layer or structure,” whether or not in any specific pattern.

Sometimes the formation of a thin passivating oxide, such as the stable, self-limiting native SiO₂ formed on Si by exposure to oxidants, is tolerated in a particle clean because it limits etching of the underlying Si. This approach is not feasible for Ge because native GeO₂ is not self-limiting, grows much faster than native SiO₂, and is soluble in water. Aqueous cleaning solutions etch the GeO₂, resulting in a loss of Ge.

SC-1 (RCA Standard Clean 1, NH₄OH:H₂O₂:H₂O˜1:1:5) is one of the most common particle-clean formulations for Si. SC-1 etches Si at a rate less than 1 nm/min, but etches Ge much more aggressively at a rate of hundreds of nm/min; the hydrogen peroxide (H₂O₂) in the solution oxidizes the Ge to GeO₂, and the water (H₂O) in the solution dissolves the GeO₂ and washes it away. Brunco et al., in Germanium MOSFET Devices: Advances in Materials Understanding, Process Development, and Electrical Performance (J. Electrochem. Soc. 2008 volume 155, issue 7, H552-H561) reported acceptable (˜3 nm/min) Ge etch rates with a 1:1:5000 dilution of SC-1, but many tools cannot reliably produce a dilution this extreme. 20-99% SiGe materials, because of their significant Ge content, are unacceptably etched (>˜20 nm/min, depending on % Ge and process parameters) by particle cleans based on SC-1 because some of the same oxidation and dissolution occurs as in pure Ge.

Therefore, a need exists for particle-clean formulations and methods that effectively remove particles from 20-99% SiGe without an unacceptable degree of etching.

### SUMMARY

The following summary presents some concepts in a simplified form as an introduction to the detailed description that follows. It does not necessarily identify key or critical elements and is not intended to reflect a scope of invention.

Solutions including tetraethylammonium hydroxide (“TEAH,” C₈H₂₁NO) and accompanying methods may be used to clean particles from 20-99% SiGe. In some embodiments, H₂O₂ is added to the TEAH solution. The solution pH may be between 8 and 12.5.

Methods of exposing the substrate to the solution may include immersing the substrate in a bath of the solution or using a spin-clean tool. Solution temperature during exposure may be between 25 C and 70 C. Exposure times may be between 15 s and 300 s.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A-1F conceptually illustrate particles, cleaning, and unwanted etching.

FIG. 2 is a block diagram of an example of a spin-cleaning apparatus.

FIG. 3 is a block diagram of an example of a bath-based cleaning apparatus.

FIG. 4 is a flowchart of an example particle-clean method for a substrate including 20-99% SiGe.

FIGS. 5A and 5B are graphs of experimental data for SiGe cleaned with embodiments of the TEAH particle clean.

### DETAILED DESCRIPTION OF EXAMPLE EMBODIMENTS

Semiconductor manufacturing can involve a large number of processes. The intent of this description is to give examples of a subset of these processes, not to describe the making of a complete device. Additional steps before and after those described are omitted for brevity. Each of the steps may include several sub-operations.

Unless the text or context clearly dictates otherwise: (1) by default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially” contemplates up to 5% variation.

“Substrate,” as used herein, may mean any workpiece on which formation or treatment of material layers is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, silicon-on-insulator, SiGe-on-insulator, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter. Furthermore, the substrates may be processed in many configurations such as single substrate processing, multiple substrate batch processing, in-line continuous processing, in-line “stop and soak” processing, or roll-to-roll processing.

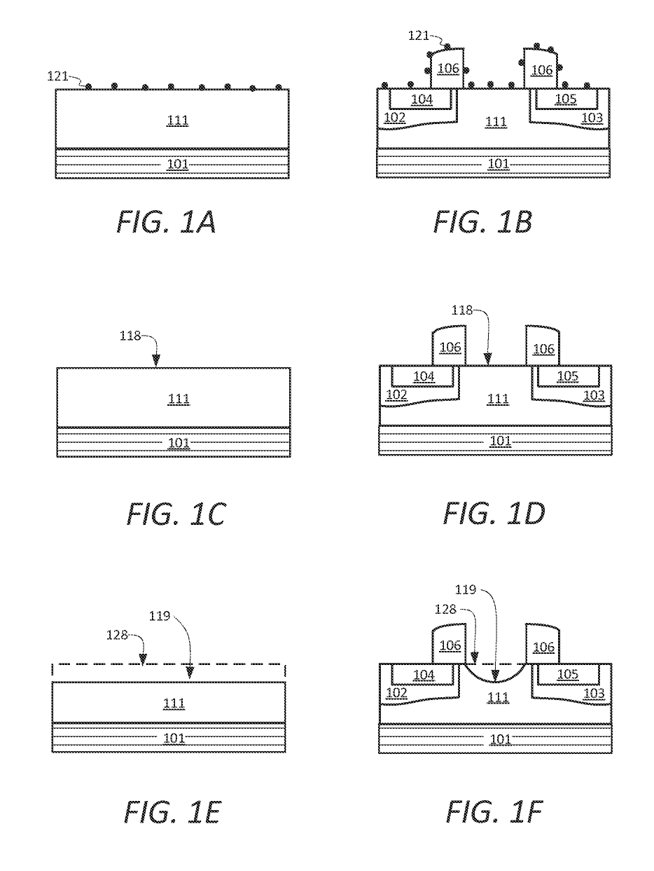

FIGS. 1A-1F conceptually illustrate particles, cleaning, and unwanted etching. FIGS. 1A and 1B show substrates, one with and one without a patterned structure, before cleaning. In FIG. 1A, substrate 101 has exposed SiGe layer 111. In some embodiments, SiGe is the bulk material of the substrate, while in others it is a layer formed on the substrate (e.g., by epitaxy, atomic layer deposition (ALD), physical vapor deposition (PVD), chemical vapor deposition (CVD, or any other suitable method of forming a SiGe layer. In some embodiments, the SiGe layer is not a “blanket” layer covering the entire substrate, but is confined to limited regions of the substrate. For example, SiGe source and drain regions may be selectively grown on non-SiGe substrates with non-SiGe channels. Particles 121 adhere to the surface of exposed SiGe layer 111; for example, by van der Waals forces, static electricity, or some other mechanism. In FIG. 1B, particles 121 adhere to a partially formed structure; for example, a metal gate transistor with source 102, drain 103, source electrode 104, drain electrode 105, and spacers 106. A dummy gate has been removed from between spacers 106, partially exposing SiGe layer 111.

FIG. 1C shows the desired result of a particle clean for the substrate of FIG. 1A, and FIG. 1D shows the desired result of a particle clean for the substrate of FIG. 1B. Particles 121 are absent and an intact surface 118 of SiGe layer 111 is left behind.

By contrast, FIG. 1E shows the unwanted result of a particle clean with SiGe etching for the substrate of FIG. 1A, and FIG. 1F shows the unwanted result of a particle clean with SiGe etching for the substrate of FIG. 1B. In both cases, SiGe layer 111 is etched below its original layer 128 to a lower level 119. In some cases, as in FIG. 1F, the top surface of SiGe layer 111 becomes uneven.

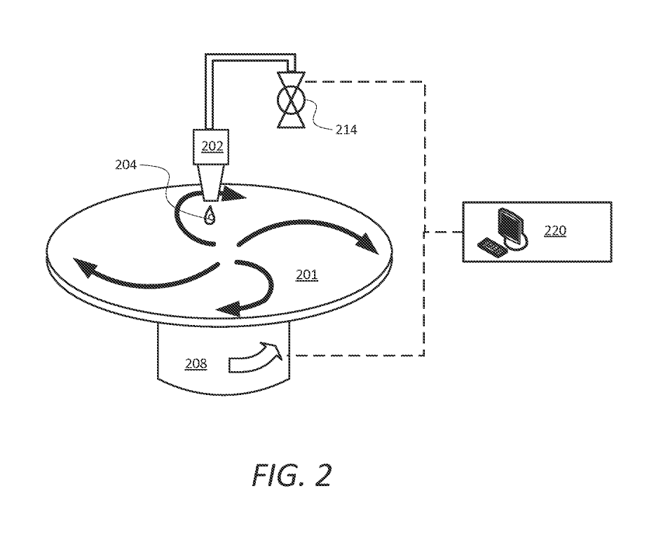

FIG. 2 is a block diagram of an example of a spin-cleaning apparatus. Substrate holder 208 holds substrate 201 under a nozzle 202. Liquid delivery system 214 provides cleaning fluid 204 to nozzle 202. Cleaning fluid 204 is shown as a drop for simplicity but may be delivered as a stream or spray. While cleaning fluid 204 exits nozzle 202 onto substrate 201, substrate holder 208 rotates substrate 201. Optionally, the apparatus may control the temperature of either substrate 201 or cleaning fluid 204. Optionally, a rinse fluid may be delivered through nozzle 202 or a similar nozzle to rinse substrate 201 after cleaning. Optionally, a drying gas may be delivered through nozzle 202 or a similar nozzle to dry substrate 201 after cleaning. Optionally, a robotic handler (not shown) may place substrate 201 on substrate holder 208 before cleaning, and remove substrate 201 from substrate holder 208 after cleaning. In some embodiments, controller 220 may automatically control the operation of substrate holder 208, liquid delivery system 214, and any heaters, coolers, gas delivery systems, or robotic handlers associated with the apparatus.

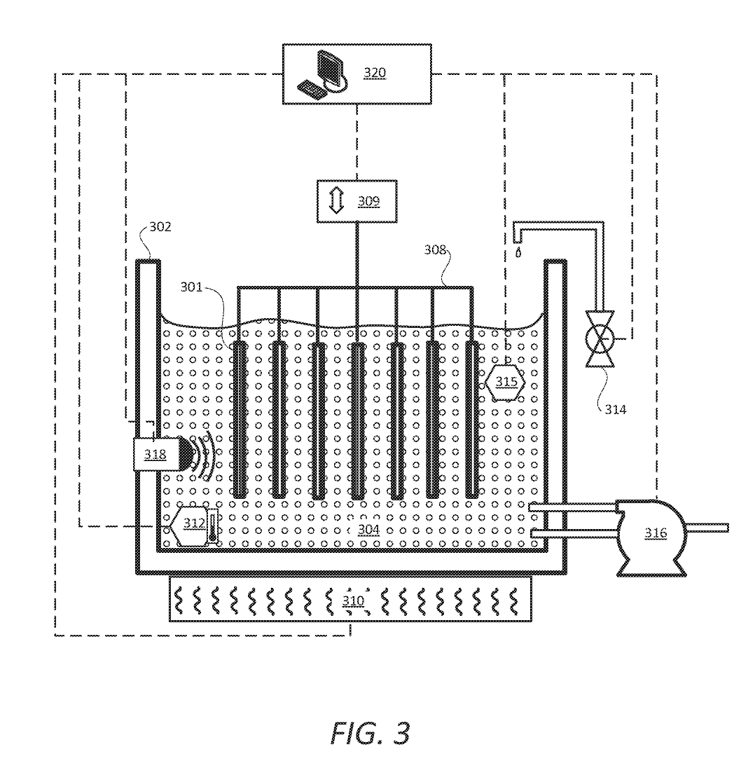

FIG. 3 is a block diagram of an example of a bath-based cleaning apparatus. Bath 302 contains cleaning solution 304. One or more substrates 301 may be immersed in bath 302 to expose substrate 301 to cleaning solution 304. Substrate 301 may be supported by substrate holder 308, which may be attached to drive 309 for moving substrate holder 308. Some embodiments of drive 308 may translate or rotate substrate 301 in multiple directions. Substrate holder 308 may be moved to insert substrates 301 into bath 302, remove substrates 301 from bath 302, or to move substrates 301 within bath 302 (e.g., to agitate cleaning solution 304 during the cleaning process).

Liquid delivery system 314 may be configured to supply additional liquids and control the composition of cleaning solution 304. For example, some components of cleaning solution 304 may evaporate or be drained from bath 302, and these components may be replenished in bath 302 by liquid delivery system 314. Various sensors 315 (e.g., conductivity sensor, weight sensor) may be used to provide signals about potential changes in composition of cleaning solution 304. Pump 316 may recirculate cleaning solution 304 in bath 302, extract an effluent stream from bath 302, and perform other functions. Heater 310 and temperature sensor 312 (e.g., a thermocouple) may be connected in a control loop to maintain cleaning solution 304 at a predetermined temperature. Some systems may include an acoustic transducer 318 to transfer ultrasonic or megasonic waves through cleaning solution 304 to substrates 301.

System controller 320 may be connected to control process conditions and other functions of the apparatus. Liquid delivery system 314, sensors 315, and pump 316 may be connected for control of the volume and composition of cleaning solution 304 by system controller 320. System controller 320 may be connected to control the operation of heater 310 based on signals received from temperature sensor 312, to maintain cleaning solution 304 at a predetermined temperature, and to adjust the on-off state, intensity, frequency, or other parameters of acoustic transducer 318. Controller 320 may include one or more memory devices and one or more processors with a central processing unit (CPU) or computer, analog and/or digital input/output connections, stepper motor controller boards, and the like. In some embodiments, controller 320 executes system control software including sets of instructions for controlling timing of operations, temperature of cleaning solution 304, composition of cleaning solution 304, and other parameters. Other computer programs, instructions, and data stored on memory devices accessible by controller 320 may also be employed in some embodiments.

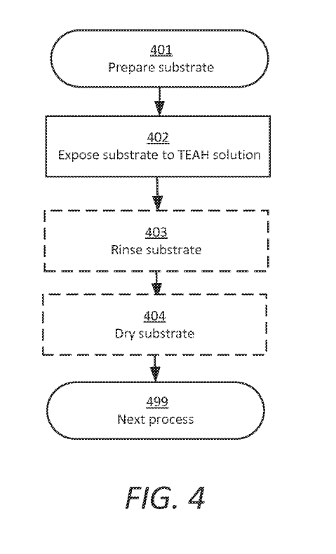

FIG. 4 is a flowchart of an example particle-clean method for a substrate including 20-99% SiGe. The substrate is prepared 401. Preparation 401 may include an etch or another clean. Next, the substrate is exposed 402 to a TEAH solution. The exposure may be in a cleaning bath or in a spin-cleaner. The TEAH solution may be 80:1-120:1 H₂O: TEAH, such as 100:1 H₂O: TEAH. Alternatively, the TEAH solution may be 1:1:80-1:1:120 TEAH:H₂O₂:H₂O, such as 1:1:100 TEAH:H₂O₂: H₂O. The pH of the TEAH solution may be between about 8 and about 11. High pH is known in the art to inhibit redeposition of particles. The process temperature may be between 25 C and 70 C. The exposure time may be 15-300 seconds. Optionally, the substrate may be rinsed 403 and/or dried 404 before the next process commences 499.

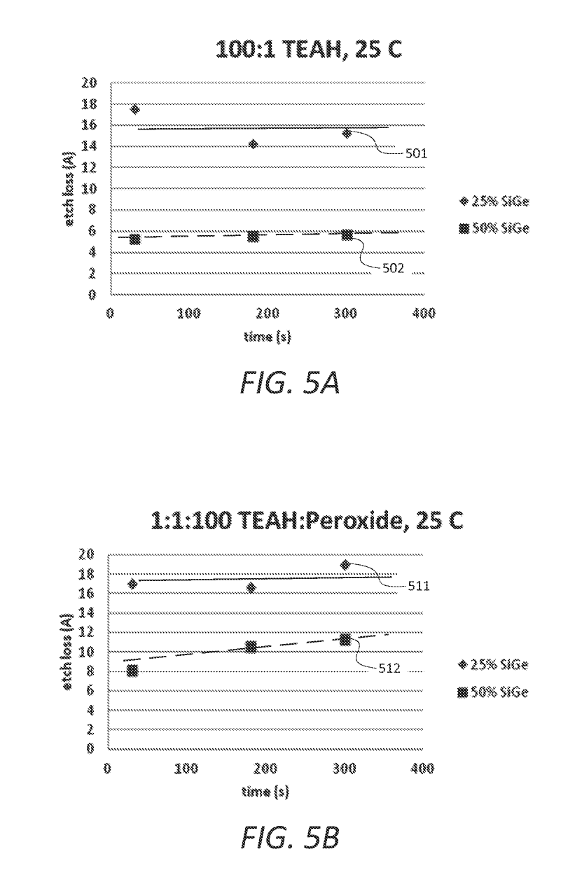

FIGS. 5A and 5B are graphs of experimental data for SiGe cleaned with embodiments of the TEAH particle clean. Etch loss in Angstrom units (1 Angstrom unit=0.1 nm) was measured by X-ray fluorescence (XRF). The slopes of the best-fit lines represent the etch rates. The non-zero y-intercepts may indicate initial rapid etching of native oxides or other surface layers. In FIG. 5A, 25% SiGe (data set 501) and 50% SiGe (data set 502) were cleaned with a 100:1 H₂O: TEAH solution. In FIG. 5B, 25% SiGe (data set 511) and 50% SiGe (data set 512) were cleaned with a 1:1:100 TEAH:H₂O₂: H₂O solution. All of the etch rates were less than 0.1 nm/min; some were less than 0.01 nm/min. These rates are as slow as, or slower than, the 1 nm/min benchmark etch rate of Si by SC-1. As such, they may be acceptable for use in many SiGe fabrication processes.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method of cleaning a substrate, the method comprising:
providing a substrate; and
exposing the substrate to a TEAH solution;
wherein the TEAH solution comprises water (H₂O) and tetraethylammonium hydroxide (TEAH, C₈H₂₁NO)
wherein a water (H₂O): TEAH ratio of the TEAH solution is between about 90:1 and 110:1; and
wherein a pH of the TEAH solution is between 8 and 12.5.

2. The method of claim 1, wherein the substrate comprises a silicon-germanium (SiGe) compound.

3. The method of claim 2, wherein the SiGe compound is between about 20% and 99% Ge.

4. The method of claim 2, wherein the SiGe compound is about 25% or about 50% Ge.

5. The method of claim 2, wherein the SiGe compound is exposed on at least part of a surface of the substrate.

6. The method of claim 2, wherein the TEAH solution etches the SiGe compound at a rate less than 3 nm/min.

7. The method of claim 2, wherein the TEAH solution etches the SiGe compound at a rate less than 1 nm/min.

8. The method of claim 2, wherein the TEAH solution etches the SiGe compound at a rate less than 0.1 nm/min.

9. The method of claim 2, wherein the TEAH solution etches the SiGe compound at a rate less than 0.01 nm/min.

10. The method of claim 1, wherein the substrate is exposed to the TEAH solution by immersion in a bath.

11. The method of claim 1, wherein the substrate is exposed to the TEAH solution in a spin-cleaning apparatus.

12. The method of claim 1, wherein the substrate is exposed to the TEAH solution at a process temperature between about 25 C and about 70 C.

13. The method of claim 1, wherein the substrate is exposed to the TEAH solution at a process temperature of about 25 C.

14. The method of claim 1, wherein the substrate is exposed to the TEAH solution at a process temperature of about 40 C.

15. The method of claim 1, wherein the substrate is exposed to the TEAH solution for a length of time between about 15 seconds and about 300 seconds.

16. The method of claim 1, wherein water (H₂O): TEAH ratio of the TEAH solution is about 100:1.

17. The method of claim 1, wherein the TEAH solution further comprises hydrogen peroxide (H₂O₂).

18. The method of claim 1, wherein a TEAH:H₂O₂: H₂O ratio in the TEAH solution is between about 1:1:80 and about 1:1:120.

19. The method of claim 1, wherein a TEAH:H₂O₂: H₂O ratio of in the TEAH solution is about 1:1:100.

20. The method of claim 1, wherein the TEAH solution removes at least one particle from a surface of the substrate.
